(19) United States
(12) Patent Application Publication
(10) Pub. No.: US 2004/0259375 A1
(43) Pub. Date: Dec. 23, 2004

(54) Removal of metal oxidation

(76) Inventor: Garo J. Derderian, Boise, ID (US)

Correspondence Address: David J. Paul, Mail Stop 01-525, 8000 S Federal Way, Boise, ID, 83716-9632, US

(21) Appl. No.: 10/463,186

(22) Filed: Jun. 17, 2003

(51) Int. Cl. H01L 21/302; H01L 21/31; H01L 21/469

(52) U.S. Cl. 438/758; 438/766; 438/770; 438/768

(57) ABSTRACT

A method of preparing an oxidized metal surface is disclosed. The oxidized metal is placed in a controlled environment and carbon monoxide is allowed to flow over the oxidized metal while the controlled environment is maintained at temperature level where the metal oxide becomes less stable than carbon dioxide so that the carbon monoxide reacts with the metal oxide to form carbon dioxide, which is removed from the controlled environment.

### FIELD OF THE INVENTION

This invention relates to a method for removing metal oxidation and in particular a semiconductor fabrication process for removing metal from copper conductors.

### BACKGROUND OF THE INVENTION

A main challenge in metal processing is preventing or removing unwanted oxidation. For example, problems with processing metals during semiconductor fabrication, such as copper (Cu) and copper interconnects specifically, are that during the cleaning of the copper that has become oxidized (copper oxide (CuO)), the Cu itself is vulnerable to being damaged in an effort to clean it by excessive exposure to heat that may cause copper atoms to diffuse into surrounding materials, react with surrounding materials and thus leave the surface of the remaining copper rough.

For example, a common copper cleaning method in semiconductor fabrication comprises exposing the copper to dilute acetic/nitric/hydrofluoric acid solution for approximately two minutes while at a temperature of around 30° C. This standard copper cleaning method will indeed clean the copper (i.e., removing any oxidation), but it also will remove around 30 Angstroms of copper and thus leave the copper surface rough, as possibly the grain boundaries of the copper etch faster than the remaining copper surface. It is desirable to develop methods that will successfully clean the copper surface without damaging the copper surface. In that light, evaluation of available information on metal and metal oxidizing agents may prove helpful.

Ellingham diagrams, such as the reproduction of the Ellingham diagram in FIG. 1, show the free energy released by the combination of a fixed amount of oxidizing agent. The relative affinities of the elements for this agent are thus shown directly. For example, according to the Ellingham diagram, CuO is not a thermodynamically stable oxide at temperatures greater than 65° C., as the diagram shows that CuO is less stable than carbon monoxide (CO) or carbon dioxide (CO₂). Similar relationships between metal oxides and oxidizing agents at certain temperatures are represented in the Ellingham diagram.

Information regarding the forming and reducing of chemical compounds, such as that presented in an Ellingham diagram, is know in the chemistry arena. With chemistry being an integral part of semiconductor fabrication and semiconductor assembly processes, utilizing chemistry in a way that is conducive to not only the semiconductor industry but to the metal processing arena as well, is a never-ending challenge. As previously discussed, removing oxidation from metals, such as copper, is an issue that is constantly being addressed with attempts to improve current oxidation removal techniques.

What is needed is an effective way to remove oxidation from metals prior to providing a conductive interconnect thereto and in particular a way to remove oxidation from copper during a semiconductor fabrication process or a semiconductor assembly process.

### SUMMARY OF THE INVENTION

An exemplary implementation of the present invention includes a method of preparing an oxidized metal surface by placing an oxidized metal in a controlled environment and flowing carbon monoxide over the oxidized metal while maintaining the controlled environment at temperature level where the metal oxide becomes less stable than carbon dioxide so that the presence of carbon monoxide reacts the metal oxide to form carbon dioxide that is then removed from the controlled environment.

Another exemplary implementation of the present invention includes a method of preparing an oxidized copper surface for a semiconductor assembly, such as during wafer fabrication or for assembly of semiconductor devices on an printed circuit board, during a semiconductor fabrication process by placing a semiconductor wafer, having a copper portion, into a processing chamber, flowing carbon monoxide over the semiconductor wafer while maintaining the processing chamber at temperature range of greater than 65° C. and less than 720° C., reacting the carbon monoxide with any copper oxide present to form carbon dioxide and to create a copper surface substantially free of oxide and removing the carbon dioxide from the processing chamber.

### BRIEF DESCRIPTION OF THE DRAWING

FIG. 1 is a reproduction of an Ellingham diagram showing free energy data of several reactants and products of metallic oxide compounds.

FIG. 2 is a flow chart depicting process steps of an exemplary implementation of the present invention.

FIG. 3 is a representation of semiconductor assembly, such a silicon wafer or semiconductor assembly substrate, placed inside a processing chamber during a metal oxide reduction process.

FIG. 4 is a cross-sectional view of a semiconductor assembly section during semiconductor fabrication showing a first metal conductor overlying a first dielectric layer and covered by a metal barrier dielectric and second dielectric layer.

FIG. 5 is a subsequent cross-sectional view taken from FIG. 4 after the placing and patterning of a photoresist, followed by the opening of a via to provide access to the first metal conductor.

FIG. 6 is a subsequent cross-sectional view taken from FIG. 5 following the exposure of the first metal conductor to carbon monoxide in a controlled environment.

FIG. 7 is a subsequent cross-sectional view taken from FIG. 6 following in-situ deposition of a conductive barrier material, such as metal nitride, followed by the deposition of a conductive material, such as metal.

FIG. 8 is a simplified block diagram of semiconductor system comprising a processor and a memory device to which the present invention may be applied.

### DETAILED DESCRIPTION OF THE INVENTION

In the following description, the terms “wafer” and “substrate” are to be understood as a semiconductor-based material including silicon, silicon-on-insulator (SOI) or silicon-on-sapphire (SOS) technology, doped and undoped semiconductors, epitaxial layers of silicon supported by a base semiconductor foundation, and other semiconductor structures. Furthermore, when reference is made to a “wafer” or “substrate” in the following description, previous process steps may have been utilized to form regions or junctions in or over the base semiconductor structure or foundation. In addition, the semiconductor need not be silicon-based, but could be based on silicon-germanium, silicon-on-insulator, silicon-on-saphire, germanium, or gallium arsenide, among others. Also, the term “semiconductor assembly” is to be understood as representing a semiconductor wafer, or a mounting member, such as a semiconductor assembly package or a printed circuit board assembly.

General embodiments of the present invention provide methods to remove oxide from metal so that the metal is substantially oxide free to allow for providing a low ohmic conductive contact thereto. Specific embodiments of the present invention provide methods during semiconductor fabrication or semiconductor assembly, to remove oxide from copper surfaces, such as copper conductors (i.e., copper interconnects) formed on a semiconductor assembly.

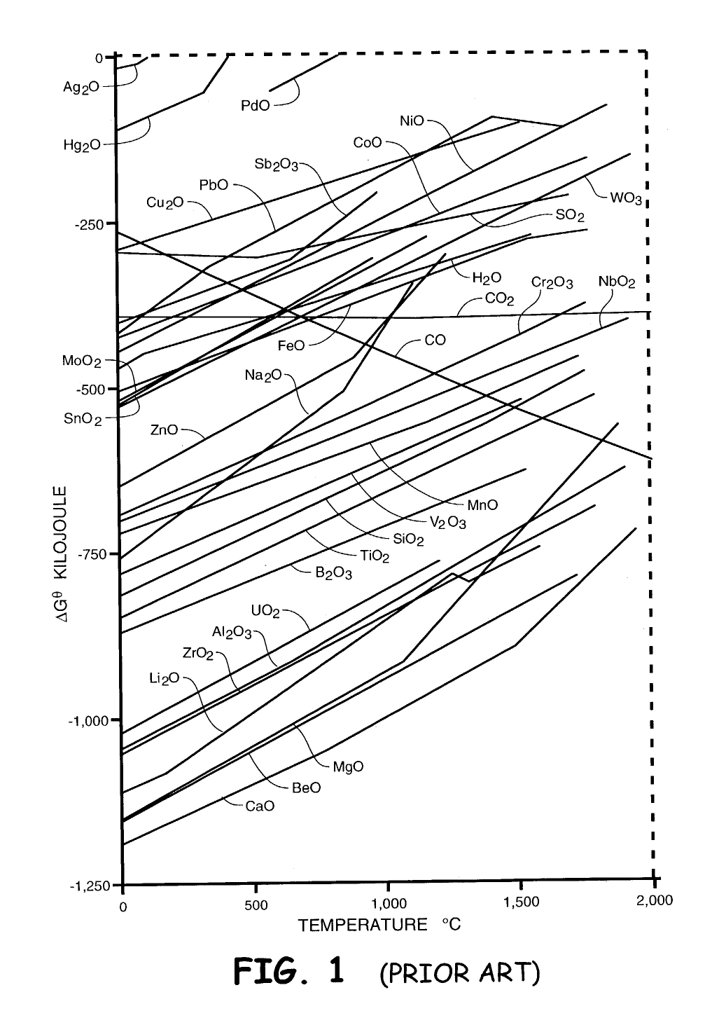

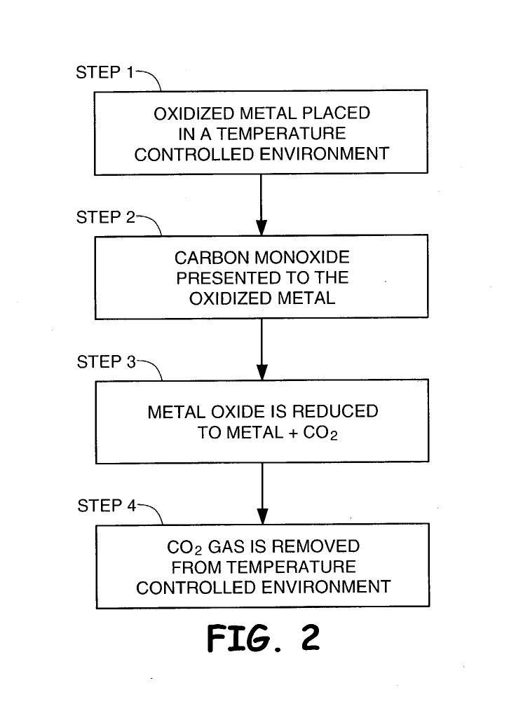

FIG. 2 is a flow chart showing general steps taken to implement an embodiment of the present invention in the industry of semiconductor fabrication or semiconductor assembly. Referring now to FIG. 2, during step 1 an oxidized metallic material is placed into a controlled environment and maintained at a temperature range whereby the oxidized metallic material is a less stable compound than CO and CO₂ as determined from known information sources, such as an Ellingham diagram represented in FIG. 1. During step 2, carbon monoxide is presented to the oxidized metal material while the temperature range of step 1 is maintained.

During step 3, the carbon monoxide reacts with the oxidized metal material and reduces the oxidized metal material to an oxide free metal and a carbon dioxide by-product and is represented in a general sense by the reaction: [M]O(s)+CO(g) [symbol] [M](s)+CO₂(g), where [M] is a metal. During step 4, the carbon dioxide can be removed from the controlled environment and the metal material is now available for further processing as desired.

The four steps of FIG. 2 can be applied to specific metal oxides by utilizing the known free energy of reaction versus temperature of metal oxide compounds, such as copper oxide (CuO), nickel oxide (NiO), and cobalt oxide (CoO), versus the free energy of reaction of carbon dioxide (CO₂) and carbon monoxide (CO). For example, taking the metal oxide compound of CuO, the Ellingham diagram shows that at a temperature that is greater than approximately 65° C., CO is a more stable compound than CuO, as is CO₂. Also shown in the Ellingham diagram is the fact that at a temperature that is less than approximately 720° C., CO is less stable than CO₂.

In order to reduce oxidized copper surface back to a copper surface substantially free of oxide, the following steps are implemented. For step 1, an oxidized copper material is placed in a controlled environment where the temperature is maintained at >65° C.<720° C. During step 2, CO (g) is introduced into the controlled environment where the temperature is being maintained at >65° C.<720° C. and allowed to flow over the oxidized copper material. During step 3, while the temperature is maintained at >65° C.<720° C. the CuO is less stable than both the CO and the CO₂, while heated to this temperature range, the CO₂ is more stable than the CO. During these conditions, the CO reacts with CuO material and thus reduces the CuO to Cu by the reaction: CuO(s)+CO(g) [symbol] Cu(s)+CO₂(g). The CO₂(g) can then expelled from the controlled environment and the copper material is now substantially free of oxidation and ready for further processing as desired.

As mentioned other metal oxide materials that fit the pattern as described by an exemplary implementation of the present invention can also be reduced to an oxide free metal and a CO₂ by-product. For example, nickel oxide (NiO) is less stable than CO and CO₂ through a temperature range of approximately greater than 475° C. and less than 720° C. and while in the presence of CO, the CO reacts with NiO material and thus reduces the NiO to Ni by the reaction:

NiO(s)+CO(g) [symbol] Ni(s)+CO₂(g).

The CO₂(g) can then be expelled from the controlled environment and the nickel material is now basically free of oxidation.

Similarly, cobalt oxide (CoO) is less stable than CO and CO₂ through a temperature range of approximately >500° C.<720° C. and while in the presence of CO, the CO reacts with CoO material and thus reduces the CoO to Co by the reaction:

CoO(s)+CO(g) [symbol] Co(s)+CO₂(g).

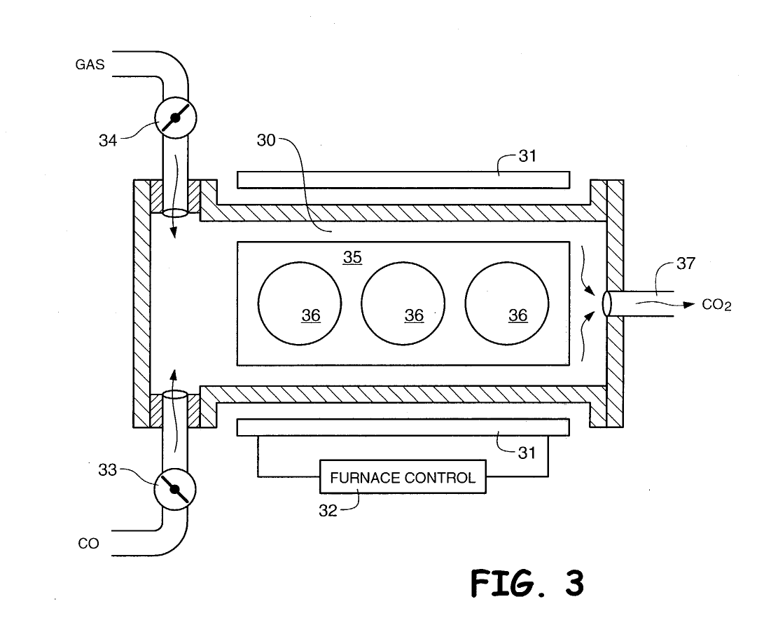

The process steps outlined in FIG. 2 for reduction of various metal oxide compounds, are specifically applicable to the semiconductor industry as depicted in FIG. 3. Referring to FIG. 3, semiconductor assembly 36 (such as an integrated circuit or a mounting member, such as a printed circuit board) is being processed for interconnecting networks and placed inside processing unit 30 (such as a process chamber), in which the environment can be controlled. The heating of processing unit 30 is produced by furnace heating elements 31 and the temperature of the processing unit is controlled by furnace control 32. Gases enter into unit 30 by way of gas control valves 33 and 34. The gas control valves have been simplified by only illustrating two valves, but are meant to represent multiple gas control valves that will provide a variety of gases needed for further processing. In conjunction with the present invention, CO gas enters into unit 30 through gas control valve 33, although CO gas may also be provided by gas control valve 34 if desired. The CO gas will flow into unit 30 and over semiconductor assemblies 36 that are being held in place by semiconductor assembly support 35. Gas is dispelled from unit 30 through gas exhaust 37 and specifically, mainly CO₂ gas will be expelled.

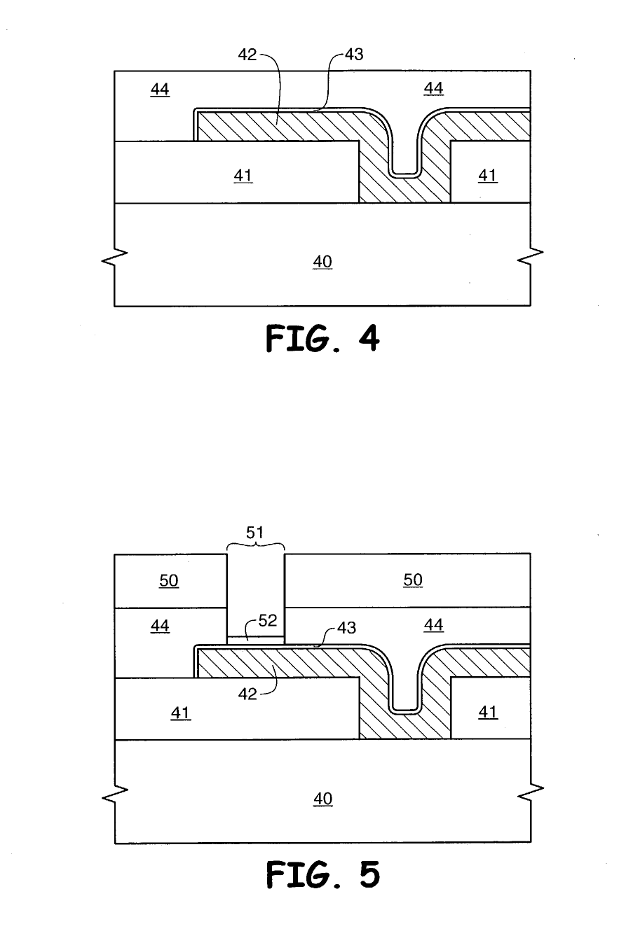

The processing unit, such as one depicted in FIG. 3, provides for an exemplary implementation of the present invention for processing a semiconductor assembly as depicted in FIG. 4-7. Referring now to FIG. 4, a semiconductor assembly (shown in cross-section) has been processed to the point where a dielectric material 41 is formed over an existing substrate 40 and has metal conductor 42, such as copper, that is used for a metal interconnect formed thereon. Copper is the preferred metal of this exemplary implementation and will be used in the following example. A barrier layer of dielectric material 43, such as silicon carbon oxide (SiCO), is formed on copper conductor 42 to serve as a copper barrier layer that will inhibit copper atoms from migrating into a second dielectric material 44 formed on the dielectric material 43.

Referring now to FIG. 5, photoresist 50 is placed and patterned to create via opening 51 that initially provides access to the subsequent metal interconnect to copper conductor 42. However, during the fabrication process copper conductor 42 has at some point developed a copper oxide layer 52, a typical result during fabrication.

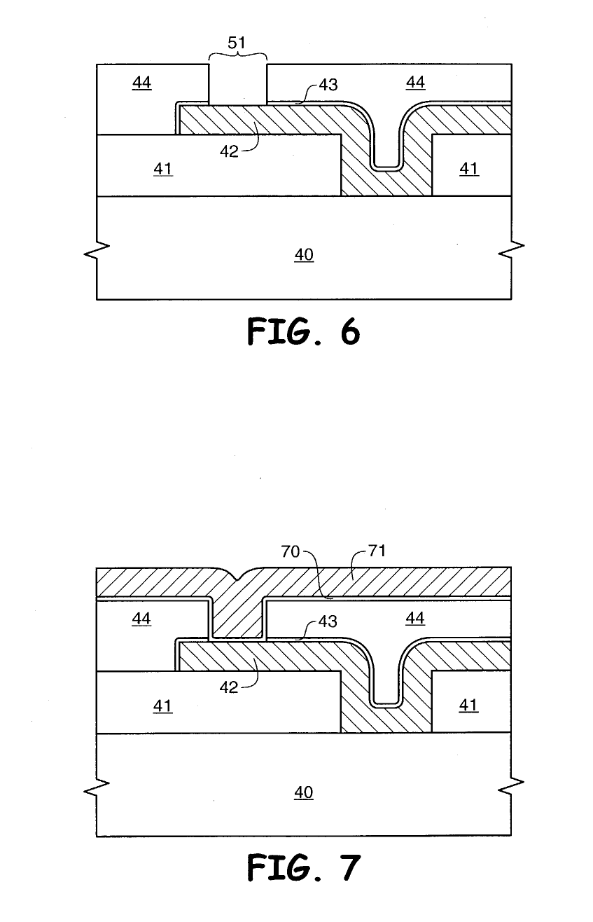

Referring now to FIG. 6, to remove copper oxide layer 52 the semiconductor assembly is placed in a processing chamber and carbon monoxide (CO) is introduced into the chamber. The CO flows over the semiconductor assembly while the processing chamber is maintained at a temperature range of greater than 65° C. and less than 720° C. Process conditions for a semiconductor production process would comprise a CO flow rate of approximately 100-1000 sccm, for a period of 30-180 sec at a temperature range >65° C.<720° C. and at a pressure of 0.5-10 Torr.

With via 51 now exposing copper oxide layer 52, the presence of the introduced CO reduces the CuO to Cu by the reaction: CuO(s)+CO(g) [symbol] Cu(s)+CO₂(g). This reaction provides a substantially oxide free Cu surface on copper conductor 42 and thus prepares the surface for further processing that preferably will be performed insitu (while the silicon wafer remains inside the processing chamber). A key to this reaction is the fact that CO₂ is more stable than CO between greater than 65° C. and up to less than 720° C. The CO₂ gas can then removed from the processing chamber. The substantially oxide free copper surface is considered to be a copper surface that is at least 90% free from oxidation, has excellent electrical conductivity and low ohmic contact.

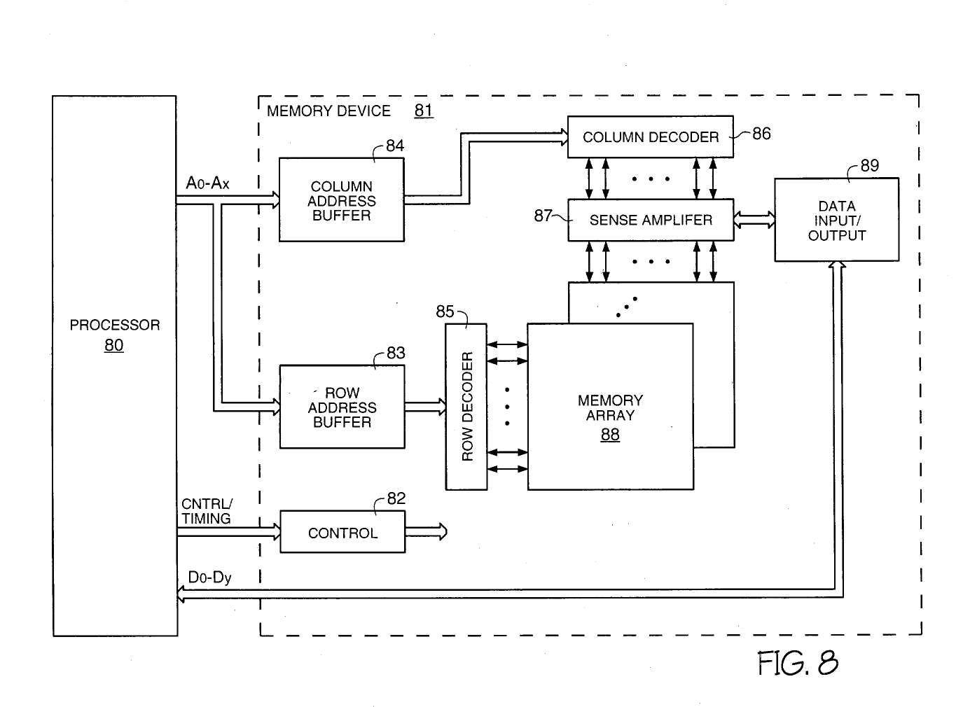

Referring now to FIG. 7, the copper surface of copper conductor 42 is ready for further processing, such as additional copper deposition, copper seeding or deposition of conductive barrier materials, such as tantalum nitride (TaN). For example, in FIG. 76, a metal barrier conductor 70, such as TaN having a thickness of approximately 10-50 Angstroms, is deposited in-situ, with a chamber temperature of approximately 300° C., which is a successful deposition temperature of TaN. Thus the TaN is deposited within a temperature range where the CO₂ remains stable and the copper will remain basically free of copper oxide and therefore allow good ohmic adhesion between the TaN and the copper surface. Preferred process conditions for an in-situ semiconductor production process the incorporates the deposition of a metal nitride barrier layer, such as TaN, would comprise a CO flow rate of approximately 500 sccm for a period of about 60 sec at a temperature range of 300-400° C. and at a pressure of approximately 1 Torr.

Next, a second metal layer 71, such as copper, is deposited on metal barrier layer 70 to form a second metal interconnect for a further process as desired for a particular semiconductor device. The conductive connections demonstrated in FIG. 4-7, represent one of many types of conductive connections used in semiconductor fabrication or semiconductor assembly and demonstrate the concepts taught by the present invention.

The present invention may be applied to a semiconductor system, such as the one depicted in FIG. 8, the general operation of which is known to one skilled in the art. FIG. 8 represents a general block diagram of a semiconductor system comprising a processor 80 and a memory device 81 showing the basic sections of a memory integrated circuit, such as row and column address buffers, 83 and 84, row and column decoders, 85 and 86, sense amplifiers 87, memory array 88 and data input/output 89, which are manipulated by control/timing signals from the processor through control 82.

It is to be understood that, although the present invention has been described with reference to a preferred embodiment, various modifications, known to those skilled in the art, may be made to the disclosed structure and process herein without departing from the invention as recited in the several claims appended hereto.

What is claimed is:

1. A method of preparing an oxidized copper surface for a semiconductor assembly during a semiconductor fabrication process comprising:
placing a semiconductor wafer, having a copper portion, into a processing chamber; and
flowing carbon monoxide over the semiconductor wafer while maintaining the processing chamber at temperature range of greater than 65° C. and less than 720° C., such that the carbon monoxide reacts with any copper oxide present to form carbon dioxide and to create a copper surface substantially free of oxide.

2. The method of claim 1, further comprises depositing a metal barrier layer in-situ to bond with the copper surface substantially free of oxide.

3. The method of claim 2, further comprises forming a second copper portion layer directly on the metal barrier layer.

4. The method of claim 1, wherein flowing the carbon monoxide comprises a carbon monoxide flow rate of approximately 100-1000 sccm for a period of 30-180 sec at the temperature range of >65° C.<720° C. and at a pressure of 0.5-10 Torr.

5. A method of preparing an oxidized copper surface for a semiconductor assembly during a semiconductor fabrication process comprising:
placing a semiconductor wafer having a copper portion, into a processing chamber;
flowing carbon monoxide over the semiconductor wafer with a carbon monoxide flow rate of approximately 500 sccm for a period of about 60 sec and at a pressure of approximately 1 Torr while maintaining the processing chamber at a temperature range of range of 300-400° C., such that the carbon monoxide reacts with any copper oxide present to form carbon dioxide and to provide a copper surface substantially free of oxide;
removing the carbon dioxide from the processing chamber; and
with the processing chamber at a temperature range of 300-400° C., depositing a tantalum nitride barrier layer in-situ to bond with the copper surface substantially free of oxide.

6. The method of claim 5, the tantalum nitride barrier layer comprises depositing a TaN layer having a thickness of approximately 10-50 Angstroms.

7. A method of preparing an oxidized metal surface for a semiconductor assembly during a semiconductor fabrication process comprising:
exposing the semiconductor assembly having an oxidized metal portion, to carbon monoxide while in a controlled environment and at a temperature that causes the reaction: [M]O(s)+CO(g) [symbol] [M](s)+CO₂(g), where [M] is a metal.

8. A method of preparing an oxidized copper surface for a semiconductor assembly during a semiconductor fabrication process comprising the step of:
exposing the semiconductor assembly having an oxidized copper portion, to carbon monoxide while in a controlled environment and at a temperature that causes the reaction: CuO(s)+CO(g) [symbol] Cu(s)+CO₂(g).

9. The method of claim 8, wherein the temperature is a temperature at which carbon dioxide is more stable than carbon monoxide.

10. The method of claim 8, wherein the temperature is in a temperature range of greater than 65° C. and less than 720° C.

11. A method for preparing an oxidized metal surface comprising:
placing an oxidized metal in a controlled environment; and
flowing carbon monoxide over the oxidized metal while maintaining the controlled environment at a temperature level where metal oxide becomes less stable than carbon dioxide so that the presence of the carbon monoxide reacts with the metal oxide to form carbon dioxide that is removed from the controlled environment.

12. A semiconductor fabrication process for preparing an oxidized metal surface comprising:
placing an oxidized metal in a controlled environment; and
flowing carbon monoxide over the oxidized metal while maintaining the controlled environment at a temperature level where metal oxide becomes less stable than carbon dioxide so that the presence of the carbon monoxide reacts with the metal oxide to form carbon dioxide that is removed from the controlled environment.

13. A method for preparing an oxidized copper surface comprising:
placing an oxidized copper material in a controlled environment; and
flowing carbon monoxide over the oxidized copper material while maintaining the controlled environment at a temperature level where copper oxide becomes less stable than carbon dioxide so that the presence of the carbon monoxide reacts with the copper oxide to form carbon dioxide that is removed from the controlled environment.

14. A method of preparing an oxidized copper surface for a semiconductor assembly during a semiconductor fabrication process comprising:
placing a semiconductor mounting member having a copper portion, into a processing chamber; and
flowing carbon monoxide over the semiconductor mounting member while maintaining the processing chamber at temperature range of greater than 65° C. and less than 720° C., such that the carbon monoxide reacts with any copper oxide present to form carbon dioxide and to create a copper surface substantially free of oxide.

15. The method of claim 14, wherein said semiconductor mounting member comprises a printed circuit board.

16. The method of claim 14, wherein flowing the carbon monoxide comprises a carbon monoxide flow rate of approximately 100-1000 sccm for a period of 30-180 sec at the temperature range of >65° C.<720° C. and at a pressure of 0.5-10 Torr.

17. A method of preparing an oxidized metal surface for a printed circuit board comprising:
exposing the printed circuit board having an oxidized metal portion, to carbon monoxide while in a controlled environment and at a temperature that causes the reaction:
[M]O(s)+CO(g) [symbol] [M](s)+CO₂(g), where [M] is a metal.

18. A method of preparing an oxidized metal surface for a printed circuit board comprising:
exposing the printed circuit board having an oxidized copper portion, to carbon monoxide while in a controlled environment and at a temperature that causes the reaction: CuO(s)+CO(g) [symbol] Cu(s)+CO₂(g).

19. The method of claim 18, wherein the temperature is a temperature at which carbon dioxide is more stable than carbon monoxide.

20. The method of claim 18, wherein the temperature is in a temperature range of greater than 65° C. and less than 720° C.
